(19) United States
(12) Patent Application Publication
(10) Pub. No.: US 2026/0114327 A1
(43) Pub. Date: Apr. 23, 2026

(54) MULTI-CHIP MODULE WITH SYNCHRONOUS CLOCKING PATHS

(71) Applicant: MARVELL ASIA PTE LTD, Singapore (SG)

(72) Inventors: Zachary BALDWIN, Burlington, VT (US); Carlos Macian Ruiz, Los Gatos, CA (US); Paul S. Zuchowski, Williston, VT (US); Mark William Kuemerle, Essex Junction, VT (US); Sidney William Allman, Stittsville (CA)

(21) Appl. No.: 19/361,813

(22) Filed: Oct. 17, 2025

Related U.S. Application Data
(60) Provisional application No. 63/708,549, filed on Oct. 17, 2024.

(51) Int. Cl. H01L 25/11; H01L 23/00; H01L 23/498; H01L 23/538; H03L 7/08

(52) U.S. Cl. CPC H10W 90/00; H10W 70/611; H10W 70/635; H10W 90/701; H03L 7/08; H10W 90/794

(57) ABSTRACT

A multi-chip module includes an interposer including first and second interposer layers each including a first plurality of contacts and a second plurality of contacts. An embedded die includes a first phase-locked loop (PLL) circuit and arranged in the interposer. A first die includes a first die layer with a third plurality of contacts connected to the first plurality of contacts of the second interposer layer and a second die layer including at least one of a first clock buffer and a first circuit. A second die includes a first die layer with a fourth plurality of contacts connected to the second plurality of contacts of the second interposer layer and a second die layer including at least one of a second clock buffer and a second circuit. A reference clock is connected to the first PLL circuit through the first interposer layer and the second interposer layer.

### CROSS-REFERENCE TO RELATED APPLICATIONS

This application claims the benefit of U.S. Provisional Patent Application No. 63/708,549 which was filed on Oct. 17, 2024. The entire disclosure of the application referenced above is incorporated herein by reference.

### FIELD

The present disclosure relates to multi-chip modules, and more particularly to multi-chip modules with synchronous clocking paths.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Modern designs require many integrated circuits (ICs) (chips or chiplets) on the same module (e.g., a multi-chip module) with support for large bandwidth interconnects between the chiplets. The interconnects traditionally have high latency and power requirements due to the need for clock domain crossings and tolerance of a wide range of process skews. Current system integration techniques do not allow high speed synchronous communication between chiplets, at least partly due to a lack of common clock mesh between the chiplets.

### SUMMARY

A multi-chip module includes an interposer including a first interposer layer and a second interposer layer including a first plurality of contacts and a second plurality of contacts. A first die includes a first die layer with a third plurality of contacts connected to the first plurality of contacts of the second interposer layer and a second die layer including a first phase-locked loop (PLL) circuit. A second die includes a first die layer with a fourth plurality of contacts connected to the second plurality of contacts of the second interposer layer and a second die layer including at least one of a first clock buffer and a first circuit. A reference clock is connected to the first PLL circuit of the second die layer of the first die through the first interposer layer, the second interposer layer, and the first die layer of the first die. A clock output of the first PLL circuit is connected to the at least one of the first clock buffer and the first circuit of the second die layer of the second die through the first die layer of the first die, the second interposer layer, and the first die layer of the second die.

In other features, a substrate including a first side including a fifth plurality of contacts connected by a plurality of micropillars to a plurality of through silicon vias of the first interposer layer. The substrate includes a second side including a sixth plurality of contacts connected to a plurality of package bumps.

In other features, the second die layer of the first die includes a second clock buffer. The clock output of the first PLL circuit is connected to the second clock buffer of the second die layer of the first die through the first die layer of the first die, the second interposer layer, and the first die layer of the first die.

In other features, the second die layer of the first die includes a second circuit. The clock output of the second clock buffer is connected to the second circuit of the second die layer of the first die through the first die layer of the first die, the second interposer layer, and the first die layer of the first die.

In other features, the second die layer of the second die includes a third clock buffer. The clock output of the first clock buffer is connected to the third clock buffer of the second die layer of the second die through the first die layer of the second die, the second interposer layer, and the first die layer of the second die.

In other features, the clock output of the third clock buffer is connected to the first circuit of the second die layer of the second die through the first die layer of the second die, the second interposer layer, and the first die layer of the second die.

In other features, the second die layer of the first die includes a first die-to-die interface. The second die layer of the second die includes a second die-to-die interface. The first die-to-die interface communicates with the second die-to-die interface communicate through the first die layer of the first die, the second interposer layer, and the first die layer of the second die.

In other features, the second die layer of the second die includes a second PLL circuit. The second die layer of the second die includes multiplexer to selectively connect the reference clock to one of the second PLL circuit or the first clock buffer. The second interposer layer is hybrid bonded to the first die and the second die.

A multi-chip module includes an interposer including a first interposer layer and a second interposer layer including a first plurality of contacts and a second plurality of contacts. An embedded die includes a first phase-locked loop (PLL) circuit and arranged in the interposer. A first die includes a first die layer with a third plurality of contacts connected to the first plurality of contacts of the second interposer layer and a second die layer including at least one of a first clock buffer and a first circuit. A second die includes a first die layer with a fourth plurality of contacts connected to the second plurality of contacts of the second interposer layer and a second die layer including at least one of a second clock buffer and a second circuit. A reference clock is connected to the first PLL circuit through the first interposer layer and the second interposer layer.

In other features, a clock output of the first PLL circuit is connected to the at least one of the first clock buffer and the first circuit of the second die layer of the first die through the second interposer layer and the first die layer of the first die. The clock output of the first PLL circuit is connected to the at least one of the second clock buffer and the second circuit of the second die layer of the second die through the second interposer layer and the first die layer of the second die.

In other features, a substrate including a first side including a fifth plurality of contacts connected by a plurality of micropillars to a plurality of through silicon vias of the first interposer layer. The substrate includes a second side including a sixth plurality of contacts connected to package bumps.

In other features, the second die layer of the first die includes a third circuit. A clock output of the first clock buffer is connected to the third circuit of the second die layer of the first die through the first die layer of the first die, the second interposer layer, and the first die layer of the first die.

In other features, the second die layer of the second die includes a third clock buffer. A clock output of the second clock buffer is connected to the third clock buffer of the second die layer of the second die through the first die layer of the second die, the second interposer layer, and the first die layer of the second die.

In other features, a clock output of the third clock buffer is connected to the second circuit of the second die layer of the second die through the first die layer of the second die, the second interposer layer, and the first die layer of the second die. The second die layer of the first die includes a first die-to-die interface. The second die layer of the second die includes a second die-to-die interface. The first die-to-die interface communicates with the second die-to-die interface communicate through the first die layer of the first die, the second interposer layer, and the first die layer of the second die.

In other features, the first die layer of the first die includes a second PLL circuit. The second die layer of the second die includes a third PLL circuit. The second die layer of the first die includes a first multiplexer configured to selectively connect the second PLL circuit to the at least one of the first clock buffer and the first circuit. The second die layer of the second die includes a second multiplexer configured to selectively connect the second PLL circuit to the at least one of the second clock buffer and the second circuit.

In other features, the second interposer layer is hybrid bonded to the first die and the second die. The embedded die is arranged in a cavity in the first interposer layer of the interposer.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF DRAWINGS

FIGS. 1 and 2 are side cross sections of an example of a module including multiple dies or chiplets and a high bandwidth interface;

FIGS. 3 to 4B are side cross sections of an example of a multi-chip module including multiple dies or chiplets with synchronous data paths and a high bandwidth interface according to the present disclosure; and

FIGS. 5 and 6B are side cross sections of an example of a multi-chip module including multiple dies or chiplets with synchronous data paths and a high bandwidth interface according to the present disclosure.

In the drawings, reference numbers may be reused to identify similar and/or identical elements.

### DESCRIPTION

The present disclosure relates to multi-chip modules including multiple integrated circuit dies, chips, or chiplets that are connected by synchronous clocking paths to allow significantly lower latency and power, which reduces total cost of ownership (TCO).

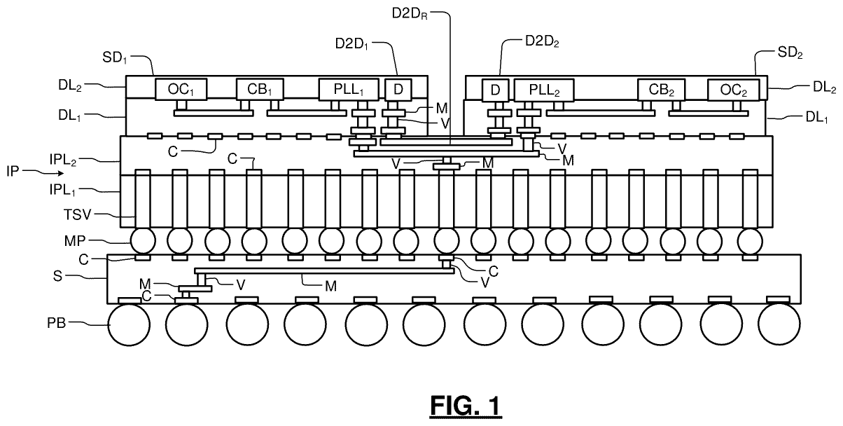

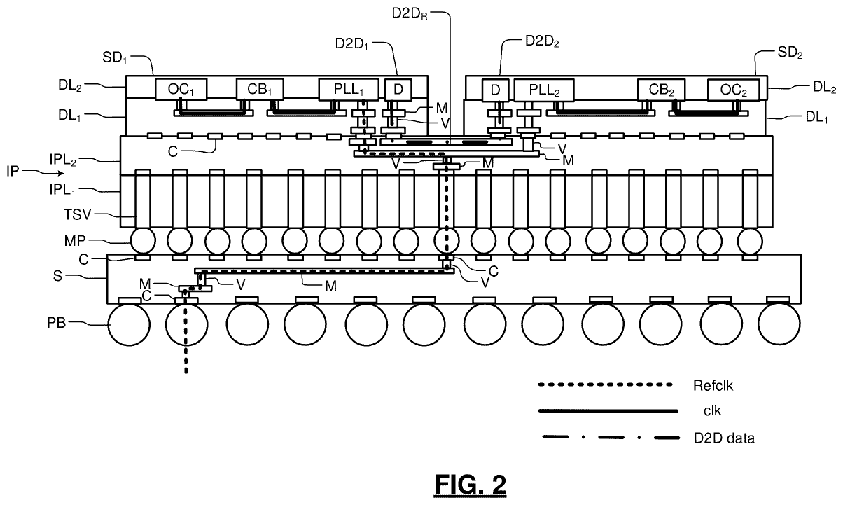

FIGS. 1 and 2 show a substrate S including contacts C connected to package bumps (PBs). A reference clock refclk is externally supplied to one of the PBs. The substrate S includes a combination of contacts C, metal connecting layers M, and vias V that route the reference clock refclk from the PB to an external contact C. The external contact C of the substrate S is connected by a micropillar (MPs) to through-silicon vias (TSVs) of a first interposer layer IPL₁ of an interposer IP.

The through-silicon vias (TSVs) of the first interposer layer IPL₁ are connected to contacts C of a second interposer layer IPL₂ of the interposer IP. The second interposer layer IPL₂ includes metal connecting layers M, vias V, and/or contacts C that distribute the reference clock to a first die layer DL₁ of a first silicon die SD₁ and a first die layer DL₁ of a second silicon die SD₂. The first die layer DL₁ of the first silicon die SD₁ includes metal connecting layers M, vias V, and/or contacts C that supply the reference clock to a first phase-locked loop circuit PLL₁ of a second die layer DL2 of the first silicon die SD₁. The first die layer DL₁ of the second silicon die SD₂ includes metal connecting layers M, vias V, and/or contacts C that supply the reference clock to a second phase-locked loop circuit PLL₂ of a second die layer DL₂ of the second silicon die SD₂.

The metal connecting layers M and the vias V of the first die layer DL₁ connect the first phase-locked loop circuit PLL₁ to a first clock buffer CB₁ and the first clock buffer CB₁ to other circuits OC₁ of the first silicon die SD₁. Likewise, the metal connecting layers M and the vias V of the first die layer DL₁ of the second silicon die SD₂ connect the second phase-locked loop circuit PLL₂ to a second clock buffer CB₂ of the second silicon die SD₂ and the second clock buffer CB₂ to other circuits OC₂ of the second silicon die SD₂.

The first silicon die SD₁ includes a first die-to-die interface (D2D₁) interface and the second silicon die SD₂ includes a second die-to-die interface (D2D₂) that enable high bandwidth communication through the metal connecting layers M, the vias V, and/or contacts C of the first die layer DL₁ of the first silicon die SD₁, the first die layer DL₁ of the second silicon die SD₂, and the second interposer layer IPL₂ to provide die-to-die routing (D2D_{R}).

The architecture in FIGS. 1 and 2 can be difficult and expensive to implement. The reference clock signal refclk is distributed to the first silicon die SD₁ and the second silicon die SD₂. The first silicon die SD₁ includes the first phase-lock loop PLL₁ and the second silicon die SD₂ includes the second phase-lock loop PLL₂. The first phase-lock loop PLL₁ and the second phase-lock loop PLL₂ generate core and input/output (I/O) clocks for the first silicon die SD₁ and the second silicon die SD₂, respectively, from the reference clock signal. Typically the reference clock is at a lower frequency than the core and input/output (I/O) clocks. The core and input/output (I/O) clocks of the first silicon die SD₁ or the second silicon die SD₂ may or may not be in phase with each other (or in phase with clocks on other dies in the module if the multi-chip module includes additional dies).

The first silicon die SD₁ and the second silicon die SD₂ are connected by the first and second die-to-die interfaces D2D₁ and D2D₂ that provide a high bandwidth interface. However, the clocks on each die may require phase alignment, clock-domain-crossing, clock recovery, etc. Circuits to support these functions are complex and consume both chip area and power, which increases cost.

Multi-chip modules according to the present disclosure use a single PLL on one of the silicon chiplets to generate a high-speed clock that is distributed to all of the chiplets arranged on the interposer. While the example shown and described below includes two chiplets, the multi-chip module can include additional chiplets. The interposer enables dense clock mesh. The interposer contains no active silicon, so when buffers are required, active silicon on the chiplet is used as a clock buffer (CB). Each local clock domain on each die is fed via a connection to the interposer where required. In some examples, the interposer is hybrid bonded to the chiplets. This approach enables a unified clock tree or mesh across multiple die on an interposer.

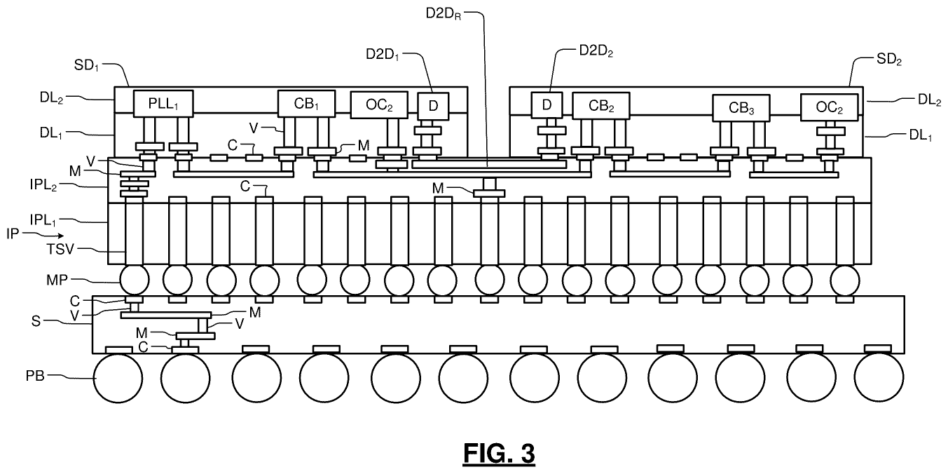

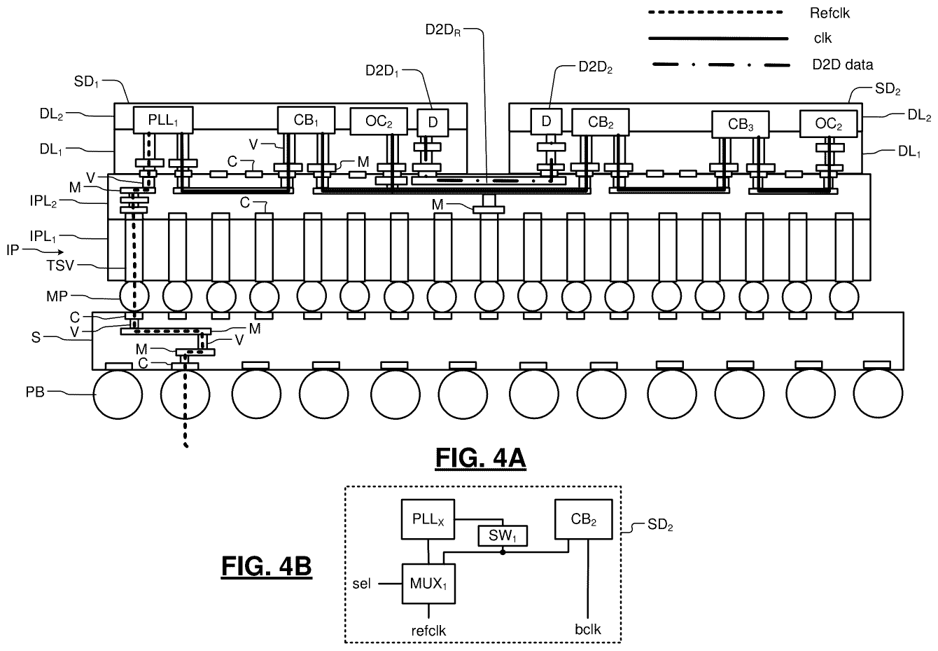

The architecture in FIGS. 3 to 4B distributes the reference clock refclk to only one die to simplify substrate routing. A single PLL is used for all components on an interposer IP. There is no need for a phase compensation block and there are no clock domain crossings. This approach enables fully synchronous D2D communication. The interposer IP is used for multi-die clock distribution. This approach eliminates most process, voltage, and temperature (PVT) variability in clock routing since clock routing is performed on the interposer IP.

FIGS. 3, 4A, and 4B show a substrate S including contacts connected to package bumps (PBs). A reference clock refclk is externally supplied to one of the PBs. The substrate S includes a combination of contacts C, metal connecting layers M, and vias V that route the reference clock refclk from the PB to an external contact C. The external contact C of the substrate S is connected by a micropillar (MPs) to through-silicon vias (TSVs) of a first interposer layer IPL₁ of an interposer IP.

The through-silicon vias (TSVs) of the first interposer layer IPL₁ are connected to contacts C of a second interposer layer IPL₂ of the interposer IP. The second interposer layer IPL₂ includes metal connecting layers M, vias V, and/or contacts C that distribute the reference clock to a first die layer DL₁ of a first silicon die SD₁. The first die layer DL₁ of the first silicon die SD₁ includes metal connecting layers M, vias V, and/or contacts C that supply the reference clock to a first phase-locked loop circuit PLL₁ of a second die layer DL₂ of the first silicon die SD₁.

The metal connecting layers M, the vias V and/or contacts of the first die layer DL₁ and the second interposer layer IPL₂ connect the first phase-locked loop circuit PLL₁ to a first clock buffer CB₁ of the first silicon die SD₁. The first clock buffer CB₁ is connected by the metal connecting layers M, the vias V and/or contacts of the first die layer DL₁ of the first silicon die SD₁ and the second interposer layer IPL2 to other circuits OC₁ of the first silicon die SD₁. The first clock buffer CB₁ is also connected by the metal connecting layers M, the vias V and/or contacts of the first die layer DL₁, the second interposer layer IPL₂, and the first die layer of the second silicon die SD₂ to a second clock buffer CB₂ of the second silicon die SD₂ (and/or to other circuits of the second silicon die SD₂). The second clock buffer CB₂ is connected by the metal connecting layers M, the vias V and/or contacts of the first die layer DL₁ of the second silicon die SD₂ and the second interposer layer IPL₂ to a third clock buffer CB₃. The third clock buffer CB₃ is connected by the metal connecting layers M, the vias V and/or contacts of the first die layer DL₁ of the second silicon die SD₂ and the second interposer layer IPL2 to other circuits OC₂ of the second silicon die SD₂.

The first silicon die SD₁ and the second silicon die SD₂ include a first die-to-die interface (D2D₁) interface and a second die-to-die interface (D2D₂), respectively, that enable communication through the metal connecting layers M, the vias V, and/or contacts C of the first silicon die SD₁, the first die layer DL₁ of the second silicon die SD₂, and the second interposer layer IPL₂ to provide die-to-die routing (D2D_{R}).

In FIG. 4B, while the second silicon die SD₂ is shown without a PLL circuit, the second silicon die SD₂ can include a PLL circuit (PLL_{X}) to allow testing of the silicon die SD₂ prior to assembly into the module or for other reasons. In some examples, a first multiplexer MUX₁ receives a clock reference refclk and outputs the clock reference refclk received by the second silicon die SD₂ to either the phase-locked loop circuit PLL_{X} or the clock buffer CB₂ depending on a select input.

To operate using the phase-locked loop circuit PLL_{X}, the clock reference refclk is connected by the first MUX₁ to the phase-locked loop circuit PLL_{X}. The output of the phase-locked loop circuit PLL_{X} is connected by an optional switch (SW) to the second clock buffer CB₂. When operating in the multi-chip module, the clock reference refclk is connected by the first MUX₁ to the second clock buffer CB₂ and the switch is opened.

The output of the phase-locked loop circuit PLL₁ can be connected to the clock buffer CB₂ and then to one of the other circuits OC₂ of the second die layer DL₂ of the second die SD₂ as shown or directly to the clock buffer CB₂ and the other circuits OC₂.

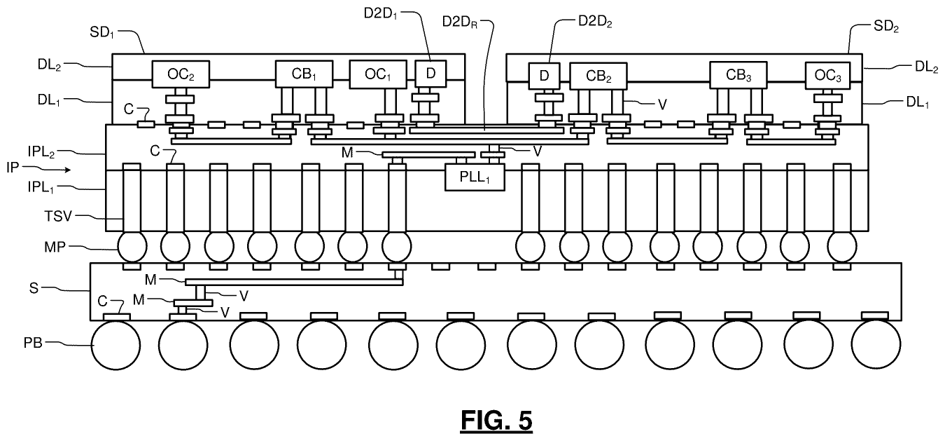

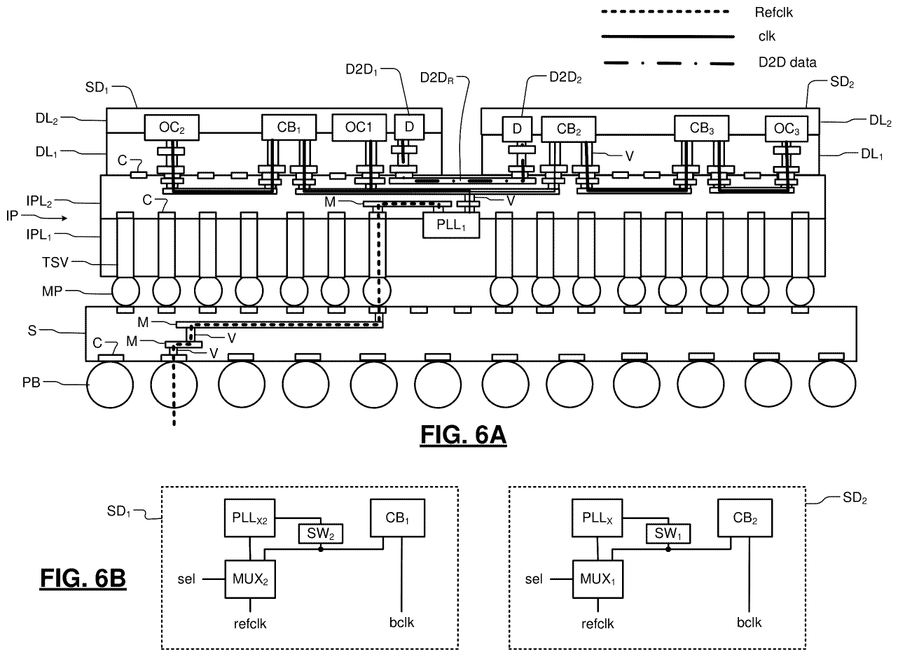

In other examples, an active silicon die includes a PLL circuit and is embedded in the interposer. Only a single PLL is required during operation of the multi-chip module. The approach saves die area of the silicon dies and allows for a unified clock mesh. FIGS. 5 to 6B show a substrate S including contacts C connected to package bumps (PBs). A reference clock is externally supplied to one of the PBs. The substrate S includes a combination of contacts C, metal connecting layers M, and vias V that route the reference clock from the PB to an external contact C. The external contact C of the substrate S is connected by a micropillar (MPs) to through-silicon vias (TSVs) of a first interposer layer IPL₁ of an interposer IP.

The through-silicon vias (TSVs) of the first interposer layer IPL₁ are connected to contacts C of a second interposer layer IPL₂ of the interposer IP. The second interposer layer IPL₂ includes metal connecting layers M, vias V, and/or contacts C that distribute the reference clock to a phase-locked loop circuit (PLL₁). In some examples, the PLL circuit PLL₁ is embedded in a cavity formed in the first interposer layer (IPL₁) and then dielectric layers, contacts C, vias V, and metal connecting layers M are patterned and deposited to form the second interposer layer IPL₂.

An output of the PLL circuit PLL₁ of the interposer IP is connected by contacts C, vias V, and/or metal connecting layers M to a first clock buffer CB₁ (and/or other circuits OC₁) of a first die layer DL₁ of a first silicon die SD₁ and to a second clock buffer CB₂ (and/or other circuits OC₁) of a second silicon die SD₂.

The metal connecting layers M, the vias V and/or contacts of the first die layer DL₁ of the first silicon die SD₁ and the second interposer layer IPL₂ connect the clock buffer CB₁ to the other circuits OC₂ of the first silicon die SD₁. The metal connecting layers M, the vias V and/or contacts of the first die layer DL₁ of the second silicon die SD₂ and the second interposer layer IPL₂ connect the clock buffer CB₂ to a clock buffer CB₃ and the clock buffer CB₃ to other circuits OC₃ of the second silicon die SD₁.

The first silicon die SD₁ and the second silicon die SD₂ include a first die-to-die interface (D2D₁) interface and a second die-to-die interface (D2D₂), respectively, that enable communication through the metal connecting layers M, the vias V, and/or contacts C of the first die layer DL₁ of the first silicon die SD₁, the first die layer DL₁ of the second silicon die SD₂, and the second interposer layer IPL₂ to provide die-to-die routing (D2D_{R}).

In FIG. 6B, while the first silicon die SD₁ and the second silicon die SD₂ are shown without PLL circuits, one or both can include a PLL circuit to allow testing of the silicon die prior to assembly into the multi-chip module or for other reasons. In some examples, the second silicon die SD₂ includes a first multiplexer MUX₁ receives a clock reference refclk and outputs the clock reference refclk to either the phase-locked loop circuit PLL_{X} or the clock buffer CB₂ depending on a select input. Likewise, the first silicon die SD₁ can include a phase-locked loop circuit PLL_{X2}. A second multiplexer MUX₂ receives a clock reference refclk and outputs the clock reference refclk to either the phase-locked loop circuit PLL_{X} or the clock buffer CB₁ depending on a select input.

The output of the PLL circuit PLL₁ in FIG. 6A can be connected to a clock buffer and/or other circuits of the second layer of the first silicon die SD₁ and/or the second silicon die SD₂. In the example in FIG. 6A, the output of the PLL circuit PLL₁ is connected to both the clock buffer CB₁ and the other circuits OC₁ of the second layer of the first silicon die SD₁. The output of the PLL circuit PLL₁ is connected to the clock buffer CB₂ of the second layer of the second silicon die SD₂ and then to the other circuits OC₃ of the second layer of the second silicon die SD₂.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the embodiments described are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

In this application, apparatus elements described as having particular attributes or performing particular operations are specifically configured to have those particular attributes and perform those particular operations. Specifically, a description of an element to perform an action means that the element is configured to perform the action. The configuration of an element may include programming of the element, such as by encoding instructions on a non-transitory, tangible computer-readable medium associated with the element.

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A multi-chip module comprising:
an interposer including a first interposer layer and a second interposer layer including a first plurality of contacts and a second plurality of contacts;
a first die including a first die layer with a third plurality of contacts connected to the first plurality of contacts of the second interposer layer and a second die layer including a first phase-locked loop (PLL) circuit;
a second die including a first die layer with a fourth plurality of contacts connected to the second plurality of contacts of the second interposer layer and a second die layer including at least one of a first clock buffer and a first circuit,
wherein a reference clock is connected to the first PLL circuit of the second die layer of the first die through the first interposer layer, the second interposer layer, and the first die layer of the first die, and
wherein a clock output of the first PLL circuit is connected to the at least one of the first clock buffer and the first circuit of the second die layer of the second die through the first die layer of the first die, the second interposer layer, and the first die layer of the second die.

2. The multi-chip module of claim 1, further comprising a substrate including a first side including a fifth plurality of contacts connected by a plurality of micropillars to a plurality of through silicon vias of the first interposer layer.

3. The multi-chip module of claim 2, wherein the substrate includes a second side including a sixth plurality of contacts connected to a plurality of package bumps.

4. The multi-chip module of claim 1, wherein:
the second die layer of the first die includes a second clock buffer, and
the clock output of the first PLL circuit is connected to the second clock buffer of the second die layer of the first die through the first die layer of the first die, the second interposer layer, and the first die layer of the first die.

5. The multi-chip module of claim 4, wherein:
the second die layer of the first die includes a second circuit, and
the clock output of the second clock buffer is connected to the second circuit of the second die layer of the first die through the first die layer of the first die, the second interposer layer, and the first die layer of the first die.

6. The multi-chip module of claim 1, wherein:
the second die layer of the second die includes a third clock buffer, and
the clock output of the first clock buffer is connected to the third clock buffer of the second die layer of the second die through the first die layer of the second die, the second interposer layer, and the first die layer of the second die.

7. The multi-chip module of claim 6, wherein the clock output of the third clock buffer is connected to the first circuit of the second die layer of the second die through the first die layer of the second die, the second interposer layer, and the first die layer of the second die.

8. The multi-chip module of claim 1, wherein:
the second die layer of the first die includes a first die-to-die interface; and
the second die layer of the second die includes a second die-to-die interface,
wherein the first die-to-die interface communicates with the second die-to-die interface communicate through the first die layer of the first die, the second interposer layer, and the first die layer of the second die.

9. The multi-chip module of claim 1, wherein the second die layer of the second die includes a second PLL circuit.

10. The multi-chip module of claim 9, wherein the second die layer of the second die includes multiplexer to selectively connect the reference clock to one of the second PLL circuit or the first clock buffer.

11. The multi-chip module of claim 1, wherein the second interposer layer is hybrid bonded to the first die and the second die.

12. A multi-chip module comprising:
an interposer including a first interposer layer and a second interposer layer including a first plurality of contacts and a second plurality of contacts;
an embedded die including a first phase-locked loop (PLL) circuit and arranged in the interposer;
a first die including a first die layer with a third plurality of contacts connected to the first plurality of contacts of the second interposer layer and a second die layer including at least one of a first clock buffer and a first circuit;
a second die including a first die layer with a fourth plurality of contacts connected to the second plurality of contacts of the second interposer layer and a second die layer including at least one of a second clock buffer and a second circuit,
wherein a reference clock is connected to the first PLL circuit through the first interposer layer and the second interposer layer.

13. The multi-chip module of claim 12, wherein:
a clock output of the first PLL circuit is connected to the at least one of the first clock buffer and the first circuit of the second die layer of the first die through the second interposer layer and the first die layer of the first die, and
the clock output of the first PLL circuit is connected to the at least one of the second clock buffer and the second circuit of the second die layer of the second die through the second interposer layer and the first die layer of the second die.

14. The multi-chip module of claim 12, further comprising a substrate including a first side including a fifth plurality of contacts connected by a plurality of micropillars to a plurality of through silicon vias of the first interposer layer.

15. The multi-chip module of claim 14, wherein the substrate includes a second side including a sixth plurality of contacts connected to package bumps.

16. The multi-chip module of claim 12, wherein:
the second die layer of the first die includes a third circuit, and
a clock output of the first clock buffer is connected to the third circuit of the second die layer of the first die through the first die layer of the first die, the second interposer layer, and the first die layer of the first die.

17. The multi-chip module of claim 12, wherein:
the second die layer of the second die includes a third clock buffer, and
a clock output of the second clock buffer is connected to the third clock buffer of the second die layer of the second die through the first die layer of the second die, the second interposer layer, and the first die layer of the second die.

18. The multi-chip module of claim 17, wherein:
a clock output of the third clock buffer is connected to the second circuit of the second die layer of the second die through the first die layer of the second die, the second interposer layer, and the first die layer of the second die.

19. The multi-chip module of claim 12, wherein:
the second die layer of the first die includes a first die-to-die interface; and
the second die layer of the second die includes a second die-to-die interface,
wherein the first die-to-die interface communicates with the second die-to-die interface communicate through the first die layer of the first die, the second interposer layer, and the first die layer of the second die.

20. The multi-chip module of claim 12, wherein:
the first die layer of the first die includes a second PLL circuit; and
the second die layer of the second die includes a third PLL circuit.

21. The multi-chip module of claim 20, wherein:
the second die layer of the first die includes a first multiplexer configured to selectively connect the second PLL circuit to the at least one of the first clock buffer and the first circuit, and
the second die layer of the second die includes a second multiplexer configured to selectively connect the second PLL circuit to the at least one of the second clock buffer and the second circuit.

22. The multi-chip module of claim 12, wherein the second interposer layer is hybrid bonded to the first die and the second die.

23. The multi-chip module of claim 12, wherein the embedded die is arranged in a cavity in the first interposer layer of the interposer.
